(19) United States
(12) Patent Application Publication
(10) Pub. No.: US 2009/0153600 A1
(43) Pub. Date: Jun. 18, 2009

(54) SYSTEM AND METHOD FOR DETECTING FLUID EJECTION VOLUME

(76) Inventors: John C. Greeven, Corvallis, OR (US); M. Isabel Borrell, Barcelona (ES); Francisco Lopez, Castellbisbal (ES); Sergio Puigardeu, Barcelona (ES); David Ramirez, Barcelona (ES)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/244,801

(22) Filed: Oct. 3, 2008

Related U.S. Application Data
(60) Provisional application No. 61/014,219, filed on Dec. 17, 2007.

(51) Int. Cl. B41J 2/17; H01L 21/00

(52) U.S. Cl. 347/6; 438/21; 257/E21.001

(57) ABSTRACT

A fluid ejection device includes an actuator, moveable to actuate a fluid pump, an optical sensor, a flag, affixed to the actuator and positioned to block the optical sensor with motion of the actuator, and a controller, coupled to the actuator and the optical sensor. The controller is configured to determine a volume of fluid pumped by the pump by detecting a change in a degree of blockage of the sensor by the flag.

### CROSS-REFERENCE TO RELATED APPLICATION

This Utility Patent Application is based on and claims the benefit of U.S. Provisional Application No. 61/014,219, filed on Dec. 17, 2007 the contents of which are hereby incorporated by reference in their entirety.

### BACKGROUND

In fluid ejection systems, such as ink jet printers, cleaning and maintenance routines are used to maintain good nozzle health, so that the fluid ejection system can have a relatively long operational life in good working condition. One common cleaning operation is priming. Priming includes a forced ejection of ink from the nozzle array, which can be accomplished using a pressure gradient. Where the pressure gradient is positive, the action is referred to as blow priming. Where the pressure gradient is negative, the action is referred to as suction priming. Fluid ejection devices such as ink jet printers often use a dedicated primer device to achieve the desired pressure gradient for priming.

In many fluid ejection devices there is no feedback about the effectiveness of the priming operation. Current priming methods, whether blow priming or suction priming, involve multiple steps and multiple components, and are susceptible to possible problems in any one of these. If a single one of the components involved in the priming routine fails, the system will not be able to extract ink from the nozzle array and perform the cleaning routine. However, priming operations are frequently driven in an open loop manner, in which the priming operation runs without providing any feedback regarding its effectiveness. With such an approach, if any given portion of the priming system fails to achieve its objectives (e.g. to clean, or to extract fluid), the control system will not have any way of knowing.

### BRIEF DESCRIPTION OF THE DRAWINGS

Various features and advantages of the present disclosure will be apparent from the detailed description which follows, taken in conjunction with the accompanying drawings, which together illustrate, by way of example, features of the present disclosure, and wherein:

FIG. 1 is a schematic view of an fluid delivery system including one embodiment of a system for detecting fluid ejection volume, showing the actuator extended up to the initial pumping position;

FIG. 2 is a partial view of the system of FIG. 1, showing the actuator extended up further than in FIG. 1;

FIG. 3 is a partial view of the system of FIG. 1, showing the actuator extended up further than in FIG. 2;

FIG. 4 is a partial view of the system of FIG. 1, showing the actuator extended up further than in FIG. 3;

FIG. 5 is a partial view of the system of FIG. 1, showing the actuator fully extended up;

FIG. 6 is a partial view of the system of FIG. 1, showing the cam rotated 180° downward, and the actuator in the fully downwardly retracted position;

FIGS. 7A-7E are close-up detail views showing the relative positions of the optical sensor and pump actuator flag throughout the range of motion of the actuator shown in FIGS. 1-6;

FIG. 8 is a close-up detail view of a flag having an inclined leading edge with a curved shape; and

FIG. 9 is a graph showing the signal from the optical sensor as a function of the flag position.

### DETAILED DESCRIPTION

Reference will now be made to exemplary embodiments illustrated in the drawings, and specific language will be used herein to describe the same. It will nevertheless be understood that no limitation of the scope of the present disclosure is thereby intended. Alterations and further modifications of the features illustrated herein, and additional applications of the principles illustrated herein, which would occur to one skilled in the relevant art and having possession of this disclosure, are to be considered within the scope of this disclosure.

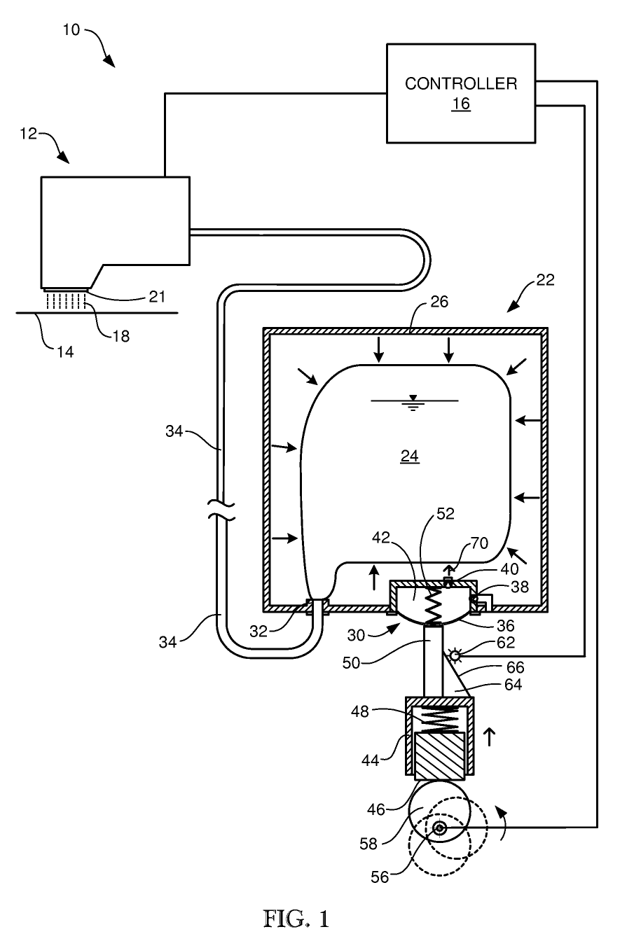

One embodiment of a fluid ejection system is shown in FIG. 1. This fluid ejection system is a scanning-type ink jet printing system 10. It is to be understood that while the description presented herein depicts an embodiment of an ink jet printing system, this is only one embodiment of a drop-on-demand fluid ejection system that can be configured in accordance with the present disclosure. While the description below specifically refers to ink, many different kinds of liquid fluids can be ejected from this type of system, such as food products, chemicals, pharmaceutical compounds, fuels, etc. The term ink is therefore not intended to limit the system to ink, but is only exemplary of any liquid that can be used. Additionally, the terms print or printing are intended to generally refer to fluid ejection onto any substrate for any purpose, and are not limited to providing visible images on paper or the like. It is also to be understood that the terms ink jet and fluid jet as used herein are both intended to refer to any drop-on-demand fluid ejection system.

The scanning-type ink jet printer system 10 shown in FIG. 1 includes a cartridge 12 that is moveably mounted on a carriage (not shown). As the cartridge traverses or scans back and forth across a sheet of print media or other substrate 14, a control system 16 activates the cartridge to deposit or eject ink droplets 18 onto the print media to form images and text. The cartridge typically includes an ink jet nozzle layer 20 containing multiple nozzles through which ink is ejected. The nozzle layer includes energy-generating elements that generate the force necessary for ejecting the fluid. Two widely used energy-generating elements are thermal resistors and piezoelectric elements. The former rapidly heats a component in the fluid above its boiling point to cause ejection of a drop of the fluid. The latter utilizes a voltage pulse to generate a compressive force on the fluid resulting in ejection of an ink drop. Those of skill in the art will recognize that the cartridge of the scanning-type ink jet printing system can be configured in a variety of ways to provide the fluid to the nozzle layer.

Ink is provided to the cartridge 12 from an ink supply station 22 that includes a primary ink reservoir 24. The ink supply station is mounted to the printing system and does not move with the carriage. This type of configuration is referred to as an “off-axis” printing system (as opposed to on-axis or on-board systems) because the ink supply is not carried by the cartridge. Because the primary ink reservoir is not part of the cartridge (and therefore does not need to move), off-board systems can generally hold a larger supply of ink than on-board systems. Additionally, off-axis printing allows the ink supply to be replaced as it is consumed, without requiring the frequent replacement of the more costly cartridge containing the fluid ejectors and nozzle system with its accompanying circuitry. Where the ink supply is separately replaceable, the ink supply is replaced when exhausted, and the cartridge need not be replaced until the end of its useful life, rather than when an initial supply of ink runs out.

While the system shown in FIG. 1 depicts only one ink reservoir 24 connected to one cartridge 12, it will be apparent that multiple ink supplies can be associated with a cartridge configured for ejecting multiple colors of ink. Color ink jet systems frequently include multiple ink supplies to contain each of the multiple ink colors that are used to produce color images. Some color ink jet printing systems use four colors of ink (e.g. cyan, yellow, magenta and black) while others use six colors of ink, and therefore include a corresponding number of ink supplies, each ink supply being connected to the scanning ink jet cartridges.

The ink supply station 22 generally includes a substantially rigid housing 26, within which is a flexible bag 28 that contains the ink. A membrane pump 30 is positioned in the bottom of the housing, and operates to pump air into the housing around the flexible bag. This air pressure squeezes the ink bag, thereby pumping ink through a septum 32, and to the cartridge 12 via the ink supply conduit 34. It is to be understood that while the ink reservoir bag 28 is shown as having a liquid surface, this is only intended to indicate the presence of a liquid, and is not intended to indicate that there is actually a free surface within the bag, or that air is contained within the bag. Ink jet printing systems and other fluid ejections systems are generally designed to prevent air from entering into the ink supply.

The membrane pump 30 can be configured in various ways. Only one of many possible embodiments of a membrane pump is shown in FIG. 1. The membrane pump includes a flexible membrane 36 and a pair of one-way air valves 38, 40. When the membrane 36 is distended, as shown in FIG. 1, the volume of the pump chamber 42 is relatively large. When the membrane is compressed into the pump chamber, this action decreases the volume of that chamber and thus increases the pressure therein, thus pumping air at a higher pressure through the second one-way valve 40 and into the housing. During this action, the first one-way valve 38 prevents air from escaping from the pump housing back to the atmosphere. Through repeated expansion and contraction of the membrane 36, pressure can be maintained on the ink bag 28, allowing a relatively constant flow of ink to the cartridge 12.

The membrane pump 30 can be mechanically actuated in various ways. The pump actuator system shown in FIGS. 1-5 is shown in very simple form, and represents only one embodiment of a membrane pump actuator system. The actuator is spring preloaded so that it keeps pumping after ink has started to flow. The pump actuator system includes a reciprocating pump actuator body 44 that is mounted atop a cam follower 46, with a coil spring 48 disposed between the cam follower and the actuator body. This spring is configured to bias the actuator upward. The actuator body includes an upwardly extending actuator arm 50 that is in contact with the membrane 36 of the membrane pump. A pump coil spring 52 is contained within the pump chamber 42, and is configured to bias the membrane outward, toward the distended position shown in FIG. 1.

The cam follower 46 is positioned to ride upon a cam 58 mounted upon a rotatable cam shaft 56 located below the actuator body 44. The cam shaft is interconnected to a motor (not shown) which is controlled by the controller 16, which controls the actuation of the cam. When the cam rotates counterclockwise to the position shown in FIG. 1, the cam lobe pushes the cam follower upward, compressing the actuator spring 48 against the interior of the actuator body 44. downward to the position shown in FIG. 1. This action pushes the actuator arm 50 against the membrane 36, thus compressing the air in the pump chamber 42 and forcing that air into the ink supply housing 26 as indicated by arrow 70. Through repeated reciprocation of the actuator in this way, pressure is maintained on the ink bag 28, allowing a relatively constant flow of ink to the cartridge 12. As ink leaves the supply reservoir 24, the force of the actuator spring 48 continually pushes air into the ink supply housing, and thus pushes ink out of the reservoir.

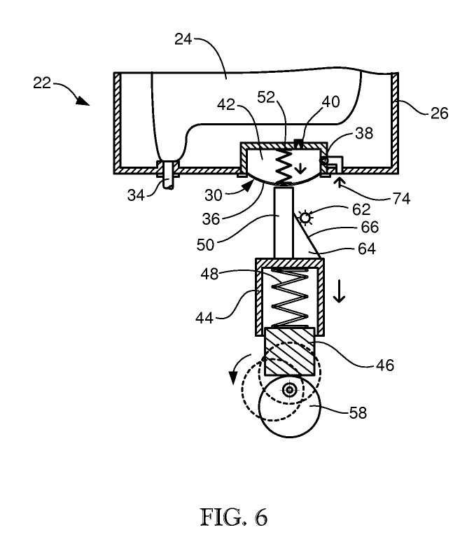

In the course of this process, the actuator body 44 will gradually rise under the force of the actuator spring 48 to the position shown in FIG. 5. In this position, the membrane 36 is fully depressed by the actuator arm 50, which is in its fully extended position in this figure. To reset the pump to begin another pumping cycle, the cam 58 rotates counter clockwise, as shown in FIG. 6. As the cam rotates to a position approximately 1800 from the position of FIG. 5, the cam follower 46 drops downward, thus releasing compression on the actuator spring 48, and allowing the actuator 44 to drop downward as well. When the pressure of the actuator is released, the pump spring 52 will also tend to push the membrane 36 back to the distended position, and can also assist in pushing the actuator downward. Pumping pressure is then restored by continued rotation of the cam to the position shown in FIG. 1, which reestablishes upward pressure against the cam follower and by extension the actuator body and the membrane.

One challenge that must be dealt with in an ink delivery system is the potential for clogs in ink conduits and passageways, including the nozzles of the cartridge nozzle layer 20. After an extended idle period, ink within an ink delivery system can gradually lose solvent, such that it either forms a solid obstruction, thereby preventing flow, or produces an increase in viscosity that resists free flow. In a multi-color ink delivery system, such as a color printer that draws ink from multiple reservoirs of different colors, an obstruction or flow reduction associated with just one of the ink colors and one of the pens can significantly affect print quality, and/or result in substantial down time, lost productivity and expense while the problem is corrected.

In order to maintain the reliability of an ink jet printing or other fluid ejection system, cartridge cleaning and maintenance routines are generally employed to prevent clogs in ink conduits and passageways in the cartridge nozzle layer 20. One of the common cleaning methods is priming. Using ink jet printers as an exemplary embodiment, an ink jet priming operation can include one or more forced ejections of ink from the cartridge 12. For example, in one embodiment of a priming operation, ink is ejected from all nozzles, following which a wiper (not shown) having ink solvent thereon is wiped across the nozzle layer to clean and wipe away any dried ink or other debris. Following the wiping step, ink is again ejected from all nozzles to flush out any remaining debris and ink solvent. The nozzle layer can then be covered with a cap (not shown) to prevent drying of ink on the nozzle layer and to maintain the cartridge in good condition for its next printing operation. When the ink is ejected in a priming operation, it is usually ejected into an ink spittoon (not shown) having an ink absorptive material. The ejection of the ink is therefore referred to as spitting, and this type priming process is sometimes referred to as a spit-wipe-spit procedure.

In order to eject ink from the cartridge during priming a pressure gradient is needed. This pressure gradient can be provided by the ink supply station pump system shown in FIG. 1. During the priming operation, a certain volume of ink will be ejected if all parts of the system are operating properly. However, if there is a failure of part of the system during the priming operation, the volume of ink that is ejected can differ from the expected volume. There are a number of factors that can lead to ink being improperly ejected from the cartridge during priming. Naturally, if the cartridge is clogged and ink cannot flow through the nozzles, this will prevent proper ink ejection during priming. If the service station caps are broken and/or are not providing good seal, this can cause or contribute to clogging of the nozzle layer. Additionally, if other pumping apparatus associated with the printing system is broken or has leaks, this can prevent the proper ejection of ink during the priming operation. Similarly, breaks leaks or clogs in ink conduits associated with the ink delivery system can also affect the ink ejection volume. Additionally, if the supplies station pump actuator or valves or other components related to it are broken, this will affect pump pressure, and can thereby hinder ink ejection accuracy.

Any one or more of the factors mentioned above (as well as others not mentioned) can prevent the ink delivery system from ejecting the proper volume of ink from the cartridge while performing the cleaning routine, or during normal operation. Ink jet printers typically include a system for indicating to a user when a supply of ink is below a certain threshold, so that the ink supply can be replenished. However, there is typically no mechanism for detecting the volume of ink that is ejected during normal operation. Consequently, the amount of ink that is ejected during a priming operation is also not typically monitored. Current priming methods, whether blow prime or suction prime, are typically driven in an open loop manner. That is, the operation is performed, but there is generally no feedback to the system to indicate whether the operation was successful. If everything in the system is in good condition the priming event should be successful, but the printer has no feedback about any possible failure that may incur. Also, there is generally no way to determine how much ink has been extracted. Thus, if any given portion of the system fails during a priming operation, the prime routine will not achieve its objectives and the printer will not have any way to know it.

Advantageously, the inventors have developed a system and method for obtaining feedback about the effectiveness of the priming system in a fluid ejection system. The system and method disclosed herein provides a way for the system to determine whether fluid is flowing through the system, and how much fluid has been ejected. Knowing the amount of fluid ejected during a priming operation can provide an indication if the system is about to fail, because the amount ejected can be compared with the known quantity that should have been ejected in any priming event.

One embodiment of a system for detecting the volume of fluid that is ejected from a fluid ejection system is an ink jet printing system illustrated in FIGS. 1-5. The ink ejection system 10 shown in FIG. 1 also includes an optical sensor 62 that is interconnected to the controller 16 and detects the position of the membrane pump actuator 44. The optical sensor detects when the actuator is out of travel and requires another pump from the cam 58. More specifically, the pump actuator body 44 includes a flag 64 that rises and falls with the actuator. A light source (not shown) is positioned to shine upon the optical sensor when the actuator is down in the position shown in FIG. 1. When the actuator rises, the flag eventually blocks the optical sensor, providing an indication to the controller 16 that the actuator has risen to its fully extended position, as shown in FIG. 5. Upon receiving this signal, the controller can actuate the cam 58 to rotate as shown in FIGS. 6 and 1 to restart the pumping action.

If the pump actuator flag 64 has a square or rectangular shape, that is, the leading edge of the flag is substantially perpendicular to the direction of motion of the flag, this can produce a sharp transition between the “not detection” and “detection” states. In such a configuration, the sensor 62 will provide essentially an on or off signal, with no intermediate conditions. The system will receive an indication when the actuator 44 reaches the extended position, but nothing else. Despite being an analog optical sensor, it thus works in a “digital” mode, having a very sharp transition between only two states. Since the volume of ink ejected during priming can be less than the amount ejected during one pump cycle of the actuator, the actuator may not reach the end of its travel during a priming event, and thus may not trigger any signal in the optical sensor.

Advantageously, the actuator flag 64 in the embodiment shown herein has an inclined leading edge 66, so that the flag can gradually block the optical sensor 62 as the actuator rises. That is, the leading edge 66 of the flag is inclined with respect to the direction of motion of the actuator, so that a degree of blockage of the sensor can be detected, in addition to an all-or-nothing signal. Thus, the ink supply station sensor can be used to measure travel in the actuator, in addition to simply indicating when another downward pump on the actuator is needed.

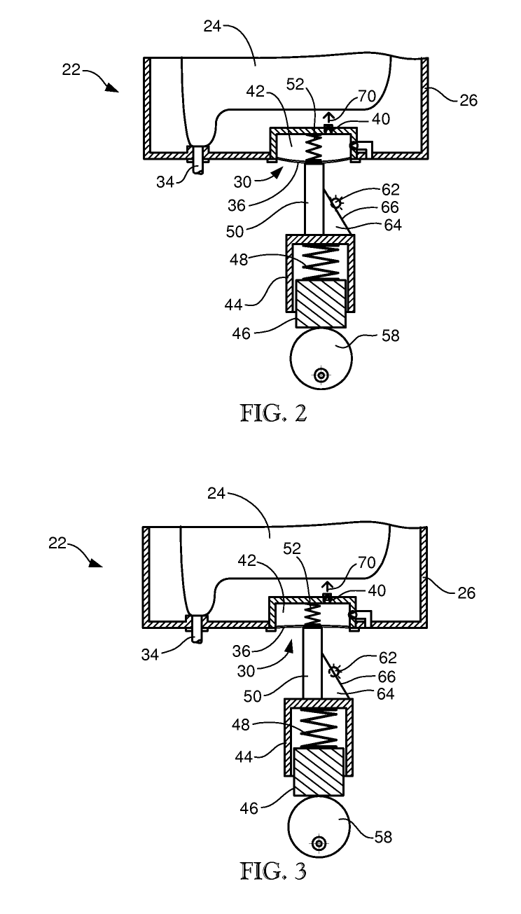

The motion of the flag 64 relative to the optical sensor and other parts of the system is illustrated in FIGS. 1-5. It is to be understood that some portions of the complete ink supply system shown in FIG. 1 are not duplicated in FIGS. 2-5 merely for the sake of clarity. As noted above, in FIG. 1 the actuator 44 is in the fully down position. In this position, the optical sensor 62 is completely unblocked by the flag 64. Turning to FIG. 2, as the actuator rises, air is pumped into the supply station housing 26 through the membrane pump outlet valve 40, as indicated by arrow 70. During the upward motion of the actuator, the inclined leading edge 66 of the flag rises, and the flag begins to block part of the optical sensor. In the position shown in FIG. 2, the optical sensor is blocked by about one fourth. Because the sensor is analog, it can measure intermediate states, and thereby allow the printer controller 16 to accurately determine how much ink has been extracted from the supply since the last “pumping” event. In other words, the partial blockage of the sensor will diminish the light that is detected, sending to the controller (16 in FIG. 1) a signal that can be converted to a volumetric change of the pump, thus allowing the controller to compute the volume of ink that has been ejected.

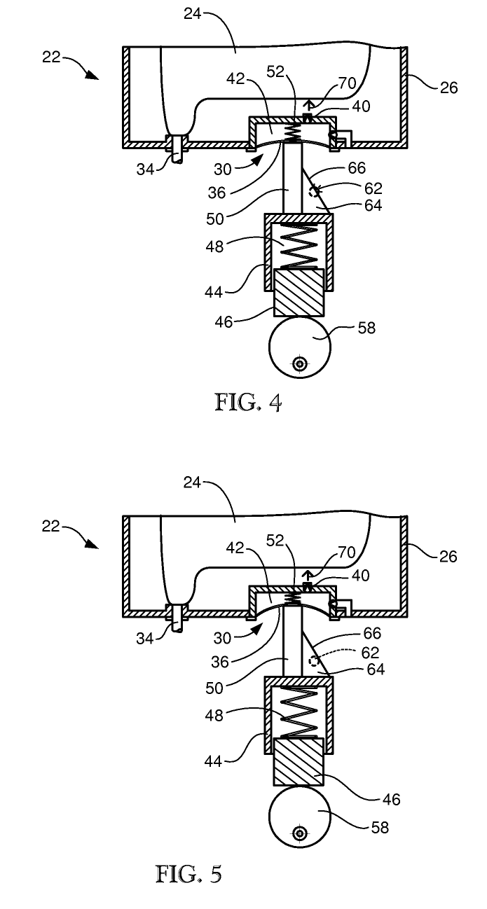

Referring to FIG. 3, as the actuator 44 continues to travel upwardly, more air will be pumped into the housing 26 as indicated by arrow 70, and a greater portion of the optical sensor 62 will be blocked. In the condition of FIG. 3, the sensor is about half blocked. In the condition shown in FIG. 4, the process has continued, and the sensor 62 is about three fourths blocked. During the upward travel of the actuator, the cam 58 remains with its large lobe oriented upwardly, maintaining pressure on the actuator spring 48.

Finally, after the actuator 44 has traveled to the limits of its upward motion, it will completely block the sensor 62, as shown in FIG. 5. At this point, complete blockage of the sensor will provide a signal to the controller (16 in FIG. 1) that indicates that another pumping action is required. To make this happen the cam 58 is rotated counter-clockwise to reset the pump, as described above with respect to FIGS. 6 and 1.

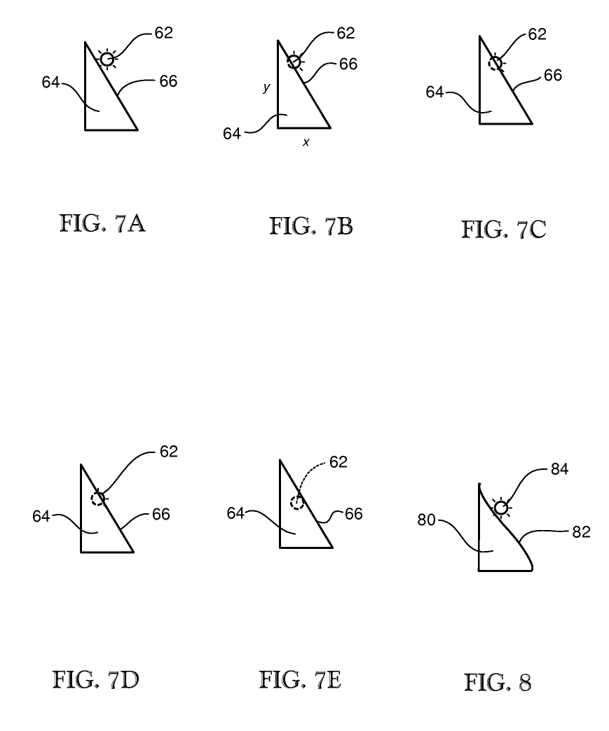

The progression of the flag 64 as it gradually moves to block the optical sensor 62 is shown in FIGS. 7A-E. In the initial position of FIG. 7A, comparable to the flag position shown in FIG. 1, the leading edge 66 is substantially out of the path of the sensor 62. In this position, the optical sensor can provide a substantially full strength signal. Moving to FIG. 7B, the flag has travelled upwardly, and the leading edge 66 is partially blocking the sensor 62. This position is like that shown in FIG. 2. As the flag continues upwardly, it blocks about half of the sensor, as shown in FIG. 7C, and then more than half of the sensor, as shown in FIG. 7D, and finally substantially completely blocks the sensor, as shown in FIG. 7E.

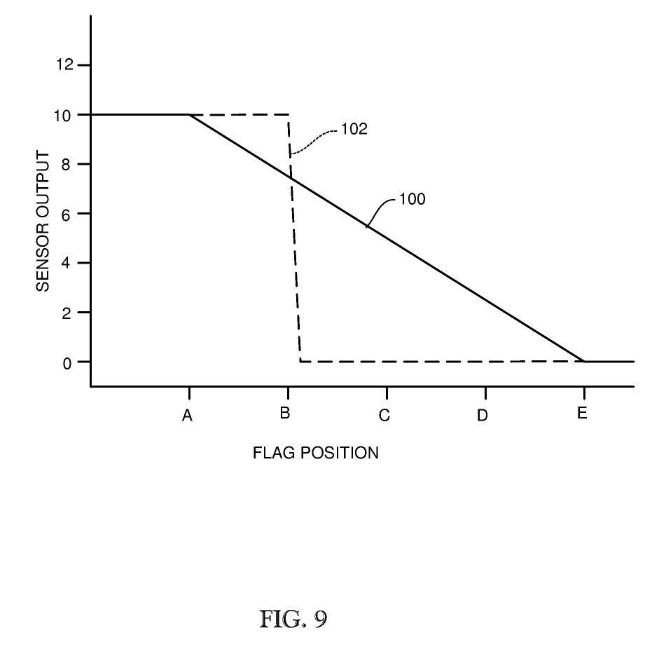

A graph representing sensor output relative to the flag position is provided in FIG. 9. The solid line 100 represents sensor output, and the positions A-E on the horizontal axis of the graph approximately correspond to the flag positions shown in FIGS. 7A-E, respectively. As can be seen, when the flag is at position A (and before) the sensor provides a substantially full strength signal (being represented by an arbitrary strength value of 10). As the flag begins to travel between positions A, B, C, etc. the optical sensor is gradually blocked, thus substantially linearly diminishing the strength of the signal. When the flag reaches position E, the sensor will be substantially completely blocked, and the signal can go substantially to zero.

For comparison, an exemplary graph of sensor output with flag position for a flag having a substantially square configuration is indicated by dashed line 102 in FIG. 9. This line illustrates how the sensor output goes from substantially full strength to zero at some abrupt point in the travel of the actuator. The present system thus provides a gradual indication of actuator position, rather than an abrupt on-off mode of operation. It is to be appreciated that while the figures illustrate certain discrete partial blockage conditions of the sensor, these are only exemplary. Because this is an analog system, there are essentially an infinite number of intermediate positions between fully blocked and fully unblocked that this sensor configuration can detect. Consequently, the system can detect a volume of ink output with relatively high accuracy.

It should also be recognized that while the inclined leading edge 66 of the flag 64 is shown as being linear, it can have other shapes. That is, nonlinear aspects of the system can be accounted for by having a flag with a curved leading edge. For example, the volumetric pumping rate of the membrane pump 30 may not be exactly linearly proportional to the linear travel of the actuator 44. While the controller 16 can be programmed to compensate for this type of non-linearity, the shape of the flag can also be adjusted to provide direct compensation in the signal from the optical sensor. For example, the flag can have an inclined leading edge with a sine wave shape. Such a configuration is shown in FIG. 8, where a flag 80 having an inclined leading edge 82 with a sine wave shape is shown. This shape can modify the rate of change in blockage of the optical sensor 84 as a function of the linear travel of the pump actuator in order to provide a desired output graph shape. Other shapes for the leading edge of the flag can also be used.

Since the travel of the actuator is proportional to the volume of ink or other fluid that is ejected from the system, this system and method thus allows the fluid ejection system to detect the amount of fluid that is ejected during a priming event. The amount of fluid that is ejected provides an indication of the success of a priming event. Small or nonexistent volumes can indicate system malfunction. The system can thus provide an indication to a user that maintenance is required, or undertake other analytical or remedial steps, depending upon the configuration of the system. This system and method thus allows the system to obtain instant feedback about the exact amount of fluid that has been pumped from the cartridge during priming. As ink jet printing and other fluid ejection systems become more and more complex, it can be desirable to have greater assurance of proper operation of the elements responsible for maintaining cartridge reliability. This system provides a closed loop monitoring system that can provide this assurance, and help increase cartridge reliability, reduce repair costs and increase user satisfaction.

Another aspect of this system relates to the field of view of the optical sensor. Optical sensors generally include a light emitting element (e.g. an LED) which is oriented to direct light at a receiver, such as a photodiode, phototransistor, CCD, etc. The field of view of the sensor is defined by the nature of the receiver and the geometry of any elements placed between the receiver (e.g. a diaphragm or similar structure) and the light emitting element. In the optical sensing system described herein, movement of the actuator is sensed as the flag moves between the light emitting element and the receiver. Some optical sensors that are used for optical detection have a field of view of about 1 mm. Such a sensor can be used in the type of pumping system shown in FIGS. 1-6. In addition to the use of an actuator flag with an inclined leading edge, as disclosed herein, a sensor with a larger field of view can also be used to provide more positional sensitivity. For example, rather than a sensor with a 1 mm field of view, a larger sensor (e.g. an infrared optical sensor, either with or without a lens) having a larger field of view (e.g. 4 or 5 mm) can be used. More generally, any device capable of measuring differences in illumination within an area can be used.

The slope of the leading edge of the flag can also be selected relative to the size of the sensor field of view. The slope of the leading edge can be selected as the ratio of the total range of travel of the actuator to the size of the sensor. This aspect of this system is illustrated in FIG. 7B, wherein the slope of the leading edge 66 is defined in terms of its rise (y) and run (x). The y factor can represent the total range of travel of the actuator during a complete pumping cycle. The x dimension can represent the size (e.g. diameter) of the sensor. Thus if the actuator has a total travel (rise) of 10 mm during one pump cycle and the sensor has a diameter (run) of 5 mm, then the slope of the leading edge can be 10/5 to provide maximum sensor accuracy.

The range of sensor sizes and range of travel of the actuator that can be used in accordance with this fluid ejection system and method are not limited, though practical considerations may limit these sizes in a given device. The inventors believe that sensors having a size of from about 1 mm to about 5 mm are most likely, and the range of travel of the actuator is likely to be in the range of from 5 mm to 20 mm, with 10 mm being a common distance of travel. However, other values can be used. It will be apparent that a smaller field of view will result in a steeper leading edge for a given range of travel. Consequently a larger sensor can help provide greater sensitivity to incremental motion of the actuator flag and less sensitivity to dimensional tolerances in the apparatus. Using this type of system the entire travel range of the actuator can be detected by the optical sensor.

The system and method disclosed herein also provides other desirable aspects in addition to measuring fluid ejection during a priming event. For example, the system can monitor the volume of fluid being ejected at any time such as during normal use. While the volume of fluid used as a function of time varies with different applications or ejection patterns, the rate of fluid usage can be detected and compared to an expected rate for a given print pattern. In addition, sudden unexpected changes in fluid usage or flow can also be detected for maintenance purposes. For example, an unexpected spike in fluid usage can indicate broken tubes or drooling cartridges. This fluid delivery system pressurizes tubes in the system whenever the system is in use. However, depending on the fluid ejection patterns, all fluid ejection cartridges may not be firing at any given time. Consequently, a comparison between the amount of fluid that is to be ejected to produce a desired ejection pattern, and the amount of fluid that has been pumped out of the supply station reservoir (24 in FIGS. 1-6) can indicate that there has been a source of fluid loss. Such fluid loss can have various causes, such as the defective operation of a regulator or other part of the system. This can create an unexpected fluid flow that could lead to drooling. This can be detected by comparing the two amounts of fluid mentioned above. Indeed, if there is a leak in any of the fluid tubes and fluid starts to flow out, the system disclosed herein should also be able to detect this because the actuator will move without the system actively ejecting fluid. This system can thus be used to detect any unexpected fluid flow whenever the fluid tubes are pressurized.

The system and method disclosed herein thus provides a method for measuring the amount of fluid ejected from a drop-on-demand cartridge using an optical sensor located at the fluid delivery station. Instead of simply providing an indication that an additional pump stroke is needed to maintain the fluid pressure, the pump actuator can include a flag having an inclined leading edge, which indicates an incremental volume of fluid that has been ejected. By detecting this volume, the system can determine whether a priming event that includes fluid ejection has been successful, or may indicate some malfunction in the system. The volumetric fluid usage can also be tracked at other times to detect other malfunctions or merely to measure fluid usage.

It is to be understood that the above-referenced arrangements are illustrative of the application of the principles disclosed herein. It will be apparent to those of ordinary skill in the art that numerous modifications can be made without departing from the principles and concepts of this disclosure, as set forth in the claims.

What is claimed is:

1. A fluid ejection device, comprising:
an actuator, moveable to actuate a fluid pump;
an optical sensor;
a variable coverage flag, affixed to the actuator and positioned to block the optical sensor with motion of the actuator; and
a controller, coupled to the actuator and the optical sensor, configured to determine a volume of fluid pumped by the pump by detecting a change in a degree of blockage of the sensor by the flag.

2. A system in accordance with claim 1, wherein the flag includes an inclined leading edge, positioned to gradually block the optical path with motion of the actuator.

3. A system in accordance with claim 2, wherein the leading edge includes a curve.

4. A system in accordance with claim 2, wherein the leading edge is substantially straight.

5. A system in accordance with claim 1, further comprising a biasing member for biasing the actuator against the pump, and a cam device, associated with the actuator, rotatable between a biasing position in which the biasing member is caused to push the actuator against the pump, and a non-biasing position in which the biasing force upon the actuator is at least partially released.

6. A system in accordance with claim 5, wherein the cam device is actuable by the controller to rotate from the biasing position to the non-biasing position when the degree of blockage of the optical path is detected to be substantially complete.

7. A system in accordance with claim 1, wherein the degree of blockage is substantially proportional to a volume of fluid pumped from the device.

8. A system in accordance with claim 1, wherein the actuator cyclically reciprocates within a travel range, and the flag is positioned to begin to block the optical path at a beginning of the travel range, and to substantially completely block the optical path at an end of the travel range.

9. A system in accordance with claim 8, wherein the flag includes an inclined leading edge having a slope approximately equal to a ratio of a length of the travel range to a size of a field of view of the optical sensor.

10. A system in accordance with claim 8, wherein the volume of fluid pumped during a time interval is equal to a total volume pumped during each reciprocation cycle times a number of complete repetitions of the reciprocation cycle during the time interval, plus a volume that is substantially proportional to the degree of blockage detected at the end of the time interval.

11. A method for detecting a volume of fluid ejected from a fluid ejection device, comprising:
biasing an actuator against a pump in the fluid ejection device, a magnitude of motion of the actuator being proportional to the volume of fluid ejected;
positioning an optical sensor adjacent to a leading edge of a variable coverage flag attached to the actuator; and
determining the volume of fluid ejected by detecting a degree of blockage of the optical sensor by the flag.

12. A method in accordance with claim 11, wherein the step of detecting a degree of blockage of the optical sensor comprises detecting a degree of blockage by an inclined leading edge of the flag.

13. A method in accordance with claim 11, wherein the step of biasing the actuator against the pump comprises linearly reciprocating the actuator within a reciprocation range, the flag beginning to block the sensor at a beginning of the reciprocation range, and substantially completely blocking the sensor at an end of the reciprocation range.

14. A method in accordance with claim 11, further comprising the sequential steps of:
moving the actuator away from contact with the pump to reset the pump; and
biasing the actuator against the pump to initiate a new pumping cycle.

15. A method in accordance with claim 14, wherein the step of determining the volume of fluid ejected comprises multiplying a volume of fluid ejected in one complete pump cycle by a number of complete pump cycles completed in a time interval, and adding the volume indicated by the degree of blockage of the optical sensor by the flag at an end of the time interval.

16. A method of making a fluid ejection device, comprising the steps of:
positioning a moveable actuator to actuate a fluid pump;
attaching to the actuator a variable coverage flag;
positioning an optical sensor adjacent to the flag, whereby the inclined leading edge selectively blocks the sensor depending upon a position of the actuator, whereby a volume of fluid pumped by the pump can be determined by detecting a change in a degree of blockage of the sensor by the flag.

17. A method in accordance with claim 16, wherein the step of attaching to the actuator a variable coverage flag comprises attaching a flag having an inclined leading edge having a slope approximately equal to a ratio of a length of a range of travel of the actuator, to a size of a field of view of the optical sensor.

18. A method in accordance with claim 16, wherein the step of attaching to the actuator a variable coverage flag comprises attaching a flag having a curved leading edge.

19. A method in accordance with claim 16, further comprising the step of attaching a biasing member to bias the actuator against the pump, and positioning a cam device adjacent to the actuator, the cam device being rotatable between a biasing position in which the biasing member is caused to push the actuator against the pump, and a non-biasing position in which the biasing force upon the actuator is at least partially released.

20. A method in accordance with claim 16, further comprising the step of interconnecting a controller to the sensor, the controller configured to determine a volume of fluid pumped by the pump by detecting a change in a degree of blockage of the sensor by the flag.
